(19) United States
(12) Patent Application Publication
(10) Pub. No.: US 2017/0179919 A1
(43) Pub. Date: Jun. 22, 2017

(54) ACOUSTIC RESONATOR AND METHOD OF MANUFACTURING THE SAME

(71) Applicant: SAMSUNG ELECTRO-MECHANICS CO., LTD., Suwon-si (KR)

(72) Inventors: Jeong Suong YANG, Suwon-si (KR); Jeong Il LEE, Suwon-si (KR); Yun Sung KANG, Suwon-si (KR); Kwang Su KIM, Suwon-si (KR); Pil Joong KANG, Suwon-si (KR)

(73) Assignee: SAMSUNG ELECTRO-MECHANICS CO., LTD., Suwon-si (KR)

(21) Appl. No.: 15/073,851

(22) Filed: Mar. 18, 2016

(30) Foreign Application Priority Data
Dec. 18, 2015 (KR) 10-2015-0181531

(51) Int. Cl. H03H 9/02; H03H 9/05; H03H 3/02; H03H 9/17

(52) U.S. Cl. CPC H03H 9/02007; H03H 9/17; H03H 9/0504; H03H 3/02

(57) ABSTRACT

An acoustic resonator and a method of manufacturing the same are provided. An acoustic resonator includes a resonating part disposed on a substrate, a cap accommodating the resonating part and bonded to the substrate, and a bonded part bonding the cap and the substrate to each other, the bonding part including at least one block disposed between a bonding surface of the cap and a bonding surface of the substrate to block a leakage of a bonding material that forms the bonded part during a bonding operation.

### CROSS-REFERENCE TO RELATED APPLICATION

This application claims the benefit under 35 USC 119(a) of Korean Patent Application No. 10-2015-0181531, filed on Dec. 18, 2015, in the Korean Intellectual Property Office, the entire disclosure of which is incorporated herein by reference for all purposes.

### BACKGROUND

1. Field

The following description relates to an acoustic resonator and a method of manufacturing the same.

2. Description of Related Art

In accordance with the recent development of communications technology, a corresponding development of signal processing technology and radio frequency (RF) component technology have become desirable.

For example, in response to the recent demand to miniaturize wireless communications devices, the miniaturization of the radio frequency component technology has become desirable. An example of technology developed to miniaturize the radio frequency component technology includes a filter having a form of a bulk acoustic wave (BAW) resonator manufactured using a semiconductor thin film wafer.

The bulk acoustic wave (BAW) resonator refers to a resonator with an element having a thin film causing resonance by depositing a piezoelectric dielectric material on a silicon wafer, which is a semiconductor substrate, and using piezoelectric characteristics of the piezoelectric dielectric material implemented as the filter.

Applications of bulk acoustic wave (BAW) resonators include small and light weight filters such as mobile communications devices, chemical and biological devices, and the like, an oscillator, a resonance element, an acoustic resonance mass sensor, and the like.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an acoustic resonator includes a resonating part disposed on a substrate, a cap accommodating the resonating part and bonded to the substrate, and a bonded part bonding the cap and the substrate to each other, the bonding part including at least one block disposed between a bonding surface of the cap and a bonding surface the substrate to block a leakage of a bonding material that forms the bonded part during a bonding operation.

The bonded part may include a first metal layer disposed on the bonding surface of the cap, a second metal layer disposed on the bonding surface of the substrate, and a third metal layer interposed between the first metal layer and the second metal layer.

The third metal layer may include tin (Sn).

The first and second metal layers may include copper (Cu) or gold (Au).

The block may be spaced apart from the first and second metal layers by a predetermined distance.

The block may be disposed on at least one of the bonding surface of the cap and the bonding surface of the substrate.

The at least one block may include a first block disposed on the bonding surface of the cap and a second block disposed on the bonding surface of the substrate.

The first block and the second block may be disposed at positions that do not face each other.

The first block and the second block may be disposed not to contact each other.

In another general aspect, a method of manufacturing an acoustic resonator involves forming a resonating part on a substrate, and bonding a cap to the substrate, in which the bonding of the cap involves providing a block on at least one of a bonding surface of the cap and a bonding surface of the substrate.

The bonding of the cap may involve forming a first metal layer on the bonding surface of the cap and forming a second metal layer on the bonding surface of the substrate, and forming a third metal layer between the first metal layer and the second metal layer to bond the cap and the substrate to each other.

The block may include the same material as that of the first metal layer or the second metal layer, and may be formed during a same process with the first metal layer or the second metal layer.

The block may be formed at a position spaced apart from the first metal layer or the second metal layer by a predetermined distance.

The forming of the third metal layer may involve melting and curing the third metal layer, and the block may impede a leakage of the molten third metal layer.

The block may be formed along an edge of the bonding surface of the cap or the bonding surface of the substrate.

A material that forms the third metal layer may have a lower melting point than a material that forms the block.

In yet another general aspect, an acoustic resonator includes a cap disposed over a resonating part and bonded to a substrate, and a bonded part disposed between a bonding surface of the cap and the substrate. The bonded part includes a block disposed along an edge of a bonding surface of the cap and a bonding material disposed on the bonding surface and abutting an inner sidewall of the block.

The bonded part may include a first metal layer disposed on the bonding surface of the cap, the first metal layer being spaced apart from the block; and the bonding material may extend from a first area between from the first metal layer and the substrate to a second area between the first metal layer and the sidewall of the block.

The block and the first metal layer may be formed of a same material, and the bonding material may include a metal having a lower melting point than the material forming the block and the first metal layer.

Other features and aspects will be apparent from the following detailed description, the drawings, and the claims.

### BRIEF DESCRIPTION OF DRAWINGS

FIG. 1 is a cross-sectional view schematically illustrating an example of an acoustic resonator.

FIG. 2 is an enlarged cross-sectional view of part A of the acoustic resonator illustrated in FIG. 1.

FIGS. 3 through 8 are views illustrating an example of a method of manufacturing an acoustic resonator.

FIG. 9 is a cross-sectional view schematically illustrating another example of a blocking block.

FIG. 10 is a plan view schematically illustrating an example of the acoustic resonator.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing various embodiments only and is not intended to limit the present description. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present description will be described with reference to schematic views. In the drawings, for example, due to manufacturing techniques and/or tolerances, modifications of the shape shown may be estimated. Thus, embodiments should not be construed as being limited to the particular shapes of regions shown herein, for example, to include a change in shape results in manufacturing. The following embodiments may also be constituted by one or a combination thereof.

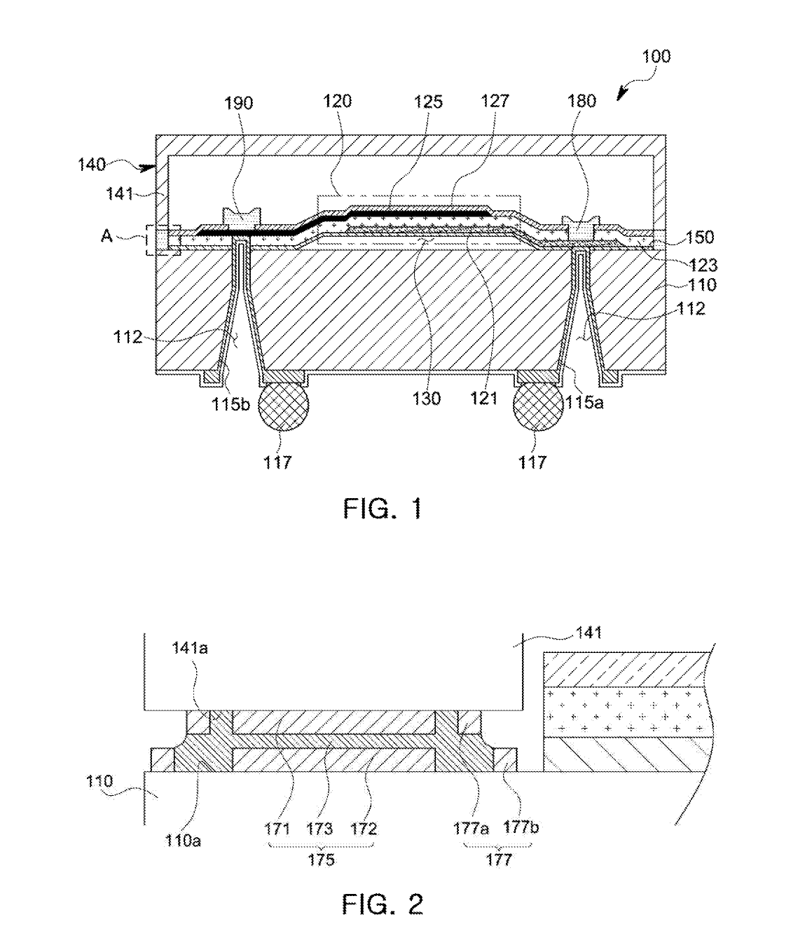

FIG. 1 illustrates a cross-sectional view of an example of an acoustic resonator, and FIG. 2 illustrates an enlarged cross-sectional view of part A of the acoustic resonator illustrated in FIG. 1.

First, referring to FIG. 1, an acoustic resonator 100 according to the illustrated example includes a substrate 110, a resonating part 120, and a cap 140.

In this example, an air gap 130 is formed between the substrate 110 and the resonating part 120, and the resonating part 120 is formed on a membrane layer 150 to be spaced apart from the substrate 110 by the air gap 130.

The substrate 110 may be formed as a silicon substrate or a silicon-on-insulator (SOI) type substrate. However, the substrate 110 is not limited thereto.

The resonating part 120 includes a first electrode 121, a piezoelectric layer 123, and a second electrode 125. The resonating part 120 may be formed by sequentially stacking the first electrode 121, the piezoelectric layer 123, and the second electrode 125 from the bottom up. In this example, the piezoelectric layer 123 is disposed between the first electrode 121 and the second electrode 125.

Because the resonating part 120 is formed on a membrane layer 150, the membrane layer 150, the first electrode 121, the piezoelectric layer 123, and the second electrode 125 may be sequentially formed on the substrate 110 to obtain the structure illustrated in FIG. 1.

The resonating part 120 may make the piezoelectric layer 123 resonate in response to signals applied to the first electrode 121 and the second electrode 125 to generate a resonance frequency and an anti-resonance frequency.

The first electrode 121 and the second electrode 125 may be formed of a metal such as gold, molybdenum, ruthenium, aluminum, platinum, titanium, tungsten, palladium, chrome, nickel, or the like.

The resonating part 120 may use an acoustic wave of the piezoelectric layer 123 to generate resonance. For example, in response to signals being applied to the first electrode 121 and the second electrode 125, mechanical vibration may occur in a thickness direction of the piezoelectric layer 123 to generate the acoustic wave.

The piezoelectric layer 123 may include zinc oxide (ZnO), aluminum nitride (AlN), quartz, and the like.

A resonance phenomenon of the piezoelectric layer 123 may occur in response to a half of a wavelength of the applied signal matching a thickness of the piezoelectric layer 123. Because electrical impedance is changed sharply when the resonance phenomenon occurs, the acoustic resonator according to an example may be used as a filter capable of selecting a frequency.

The resonance frequency may be determined by the thickness of the piezoelectric layer 123, the first electrode 121, the second electrode 125 that surrounds the piezoelectric layer 123, inherent acoustic wave velocity of the piezoelectric layer 123, and the like.

For example, as the thickness of the piezoelectric layer 123 is reduced, the resonance frequency may be increased.

Referring to FIG. 1, the resonating part 120 further includes a protection layer 127. In this example, the protection layer 127 is formed on the second electrode 125 to prevent the second electrode 125 from being exposed to an external environment.

The first electrode 121 and the second electrode 125 are formed on an outer surface of the piezoelectric layer 123, and are connected to a first connection electrode 180 and a second connection electrode 190, respectively.

The first connection electrode 180 and the second connection electrode 190 may be provided to confirm characteristics of the resonator and the filter, and to perform a required frequency trimming. However, the first connection electrode 180 and the second connection electrode 190 are not limited thereto.

In this example, the resonating part 120 is spaced apart from the substrate 110 by the air gap 130 in order to improve a quality factor.

For example, by forming the air gap 130 between the resonating part 120 and the substrate 110, the acoustic wave generated from the piezoelectric layer 123 may not be affected by the substrate 110.

Further, reflective characteristics of the acoustic wave generated from the resonating part 120 may be improved by the air gap 130. Because the air gap 130, which is an empty space, has an impedance that is close to infinity, the acoustic wave may not be lost by using the air gap 130, and may remain in the resonating part 120.

Therefore, by reducing loss in the acoustic wave in a longitudinal direction by the air gap 130, a quality factor value of the resonating part 120 may be improved.

In this example, a plurality of via holes 112 penetrating through the substrate 110 is formed in a lower surface of the substrate 110. In addition, connection conductors 115a and 115b may be formed in the respective via holes 112.

The connection conductors 115a and 115b are formed on inner surfaces of the via holes 112, that is, overall inner walls of the via holes 112, but are not limited thereto.

Further, one end of the connection conductors 115a and 115b are connected to external electrodes 117 formed on the lower surface of the substrate 110, and the other end thereof are connected to the first electrode 121 or the second electrode 125.

In this example, a first connection conductor 115a electrically connects the first electrode 121 and the external electrode 117 to each other, and a second connection conductor 115b electrically connects the second electrode 125 and the external electrode 117 to each other.

Therefore, the first connection conductor 115a may penetrate through the substrate 110 and the membrane layer 150, and may be electrically connected to the first electrode 121, and the second connection conductor 115b may penetrate through the substrate 110, the membrane layer 150, and the piezoelectric layer 123, and may be electrically connected to the second electrode 125.

Meanwhile, although FIG. 1 illustrates and describes only two via holes 112 and two connection conductors 115a and 115b, the number of via holes and connection conductors is not limited to thereto. A great number of via holes 112 and connection conductors 115a and 115b may be provided, as needed.

The cap 140 is provided to protect the resonating part 120 from an external environment.

The cap 140 is formed in a cover form including an internal space in which the resonating part 120 is accommodated. The cap 140 may hermetically seal the resonating part 120. Thus, the cap 140 is bonded to the substrate so that a side wall 141 thereof surrounds the resonating part 120.

Further, a lower surface of the side wall 141 may be used as a bonding surface 141a with the substrate 110.

In this example, the cap 140 is bonded to the substrate 110 by a solid liquid inter-diffusion (SLID) bonding, and a resultant bonded part 175 is formed between the bonding surface 141a of the cap and the bonding surface 110a of the substrate.

As the SLID bonding, a Cu—Sn bonding may be used. However, an Au—Sn bonding may also be used.

Referring to FIG. 2, the bonded part 175 includes a first metal layer 171 formed on the cap 140, a second metal layer 172 formed on the substrate 110, and a third metal layer 173 interposed between the first metal layer 171 and the second metal layer 172.

The first metal layer 171 and the second metal layer 172 may be formed of a Cu material, and the third metal layer 173 may be formed of a Sn material.

In addition, the third metal layer 173 extends to outer sides of the first and second metal layers 171 and 172.

The extended portions may be portions formed by the Sn bonding material that is melted during the SLID bonding process and leaks outside of the space between the first and second metal layers 171 and 172 before being cured.

Because the third metal layer 173 is formed by spreading the molten Sn bonding material between the first and second metal layers 171 and 172, the third metal layer 173 protruding to the outer sides of the first and second metal layers 171 and 172 is likely to be separated from the third metal layer 173 and to be introduced into the resonating part 120. Further, in the event that an excessive amount of the molten Sn flows out to the outer sides of the first and second metal layers 171 and 172, an amount of Sn bonding the first and second metal layers 171 and 172 to each other may be decreased in the region between the first and second metal layers 171 and 172, thereby deteriorating coupling reliability.

Thus, the acoustic resonator includes at least one blocking block 177 at the outer side of the first metal layer 171 or the second metal layer 172.

Referring to FIG. 2, the blocking block 177 is disposed at a position spaced apart from the first metal layer 171 or the second metal layer 172 by a predetermined distance, and is disposed within the area corresponding to the bonding surface 141a of the cap 140.

The blocking block 177 has an elongated shape along the edges of the bonding surface 141a of the cap 140. The blocking block 177 may have a continuous ring shape along the bonding surface 141a in a plan view, or another geometric shape along the bonding surface 141a. However, the blocking block 177 is not limited thereto, and may also be formed in, for example, a dashed-lines shape under the bonding surface 141a.

In this example, the blocking block 177 is formed to have a thickness substantially similar to that of the first metal layer 171 or the second metal layer 172. However, the thickness of the blocking block 177 is not limited thereto. For example, as long as the blocking block 177 may block a flow of the molten Sn, the blocking block 177 may be formed to have various thicknesses.

FIG. 2 illustrates an example in which the blocking blocks 177 are formed on both of the cap 140 and the substrate 110. However, a configuration of the present description is not limited thereto, and the blocking block 177 may also be formed on only any one of the cap 140 and the substrate 110.

Further, in the example in which the blocking blocks 177 are formed on both of the cap 140 and the substrate 110, a blocking block 177a (hereinafter referred to as a first blocking block) formed on the cap 140 and a blocking block 177b (hereinafter referred to as a second blocking block) formed on the substrate 110 may be disposed not to face or coincide with each other.

For example, the first blocking block 177a is disposed on an inner side of the second blocking block 177b. However, the first blocking block 177a and the second blocking block 177b may be variously modified. Conversely, for example, the second blocking block 177b may be disposed on an inner side of the first blocking block 177a, and so forth.

This is a configuration to smoothly and externally discharge air within the bonded part 175 upon forming the bonded part 175. In an example in which the first blocking block 177a and the second blocking block 177b are in contact with each other and are bonded to each other during a process of forming the bonded part 175, an internal space of the blocking block 177 may be sealed by the first blocking block 177a and the second blocking block 177b. Thus, air in the blocking block 177 may not be externally discharged, and in an example in which the air in the blocking block 177 is expanded by heat, a bonding defect may result from air pressure.

However, in an example in which the first blocking block 177a and the second blocking block 177b are disposed not to coincide with each other as in the embodiment illustrated in FIG. 2, because a passage through which the air in the blocking block 177 may be discharged is provided, an occurrence of the above-mentioned bonding defect may be prevented.

The blocking block 177 illustrated in FIG. 2 may be formed of the same material (e.g., copper (Cu)) as that of the first metal layer 171 or the second metal layer 172. The reason is that the blocking block 177 may be formed together with the first metal layer 171 or the second metal layer 172 during a same process, but a configuration of the present disclosure is not limited thereto.

Meanwhile, although FIG. 2 illustrates an example in which the entire first blocking block 177a and the entire second blocking block 177b are not in contact with each other, the blocking block 177 is not limited to the above-mentioned configuration, and may be variously modified.

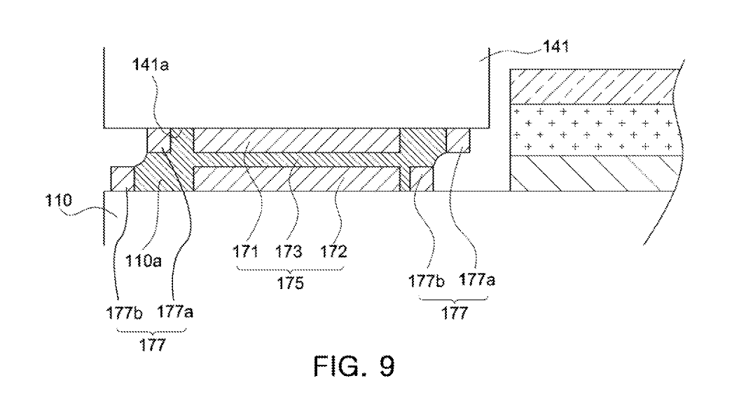

FIG. 9 illustrates a cross-sectional view of another example of a blocking block, similar to FIG. 2.

Referring to FIG. 9, a blocking block 177 disposed at an outer side of the bonded part 175 includes a first blocking block 177a and a second blocking block 177b. The first blocking block 177a is disposed to be adjacent to the bonded part 175 as compared to the second blocking block 177b. In addition, another blocking block 177 disposed at an inner side of the bonded part 175 includes a second blocking block 177b is disposed to be adjacent to the bonded part 175 as compared to a first blocking block 177a.

In this example, the first blocking block 177a and the second blocking block 177b have a section in which at least portions thereof overlap each other. However, because the entire first blocking block 177a and the entire second blocking block 177b do not overlap each other, the passage through which the air in the bonded part 175 may be discharged is still provided.

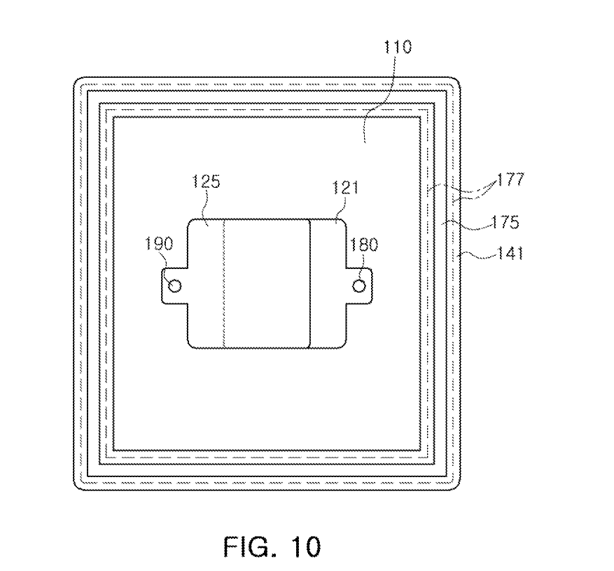

FIG. 10 illustrates a plan view of an example of an acoustic resonator according to FIG. 1. Referring to FIG. 10, the acoustic resonator includes a cap 140 having a side wall 141 that forms a rectangular shape. The blocking blocks 177 are disposed along an inner edge and an outer edge of the side wall 141 to form a closed shape or a loop, such as a rectangular shape similar to that of the side wall 141. While an acoustic resonator having a cap 140 and blocking blocks 177 with a rectangular shape is illustrated in FIG. 10, in another example, other geometric shapes, such as a ring shape, may be applied. In yet another example, the blocking blocks 177 may not form a closed shape. For instance, the blocking blocks 177 may be provided only under a portion of the side wall 141, such as at least two opposing sides of the cap 140, or in a dash line, to preventing the leakage of the bonding material. The resonating part 120 is accommodated between the substrate 110 and the cap 140. Various features of the acoustic resonator are omitted in FIG. 10. For these features, the description of the acoustic resonator in reference to FIG. 1 applies to the acoustic resonator of FIG. 10.

Next, an example of a method of manufacturing an acoustic resonator will be described.

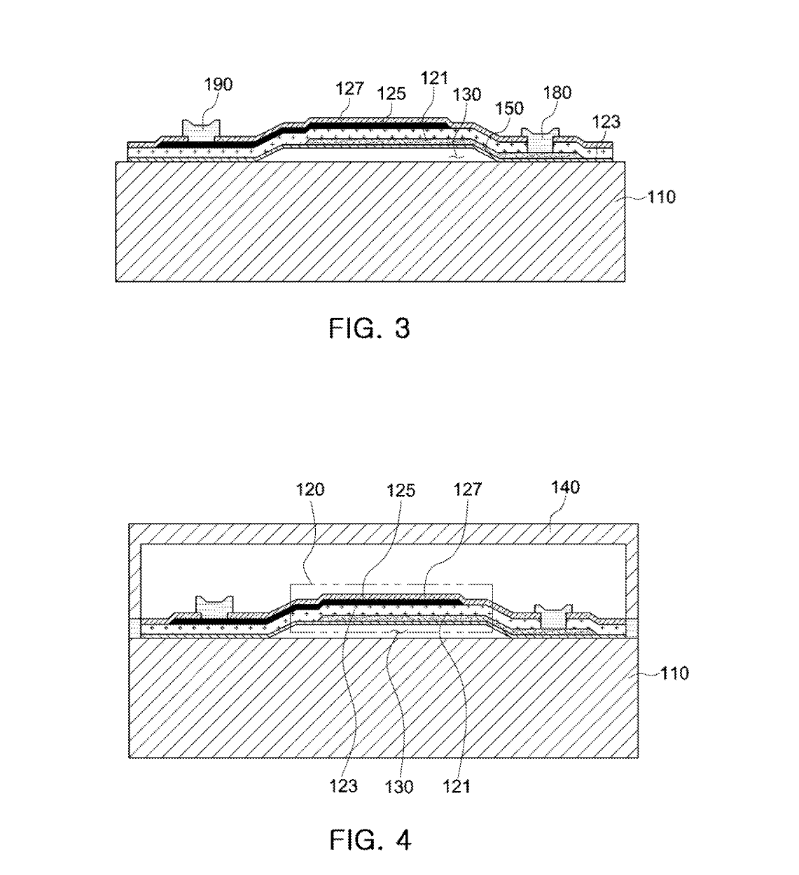

FIGS. 3 through 7 are views illustrating an example of a method of manufacturing an acoustic resonator.

First, referring to FIG. 3, the resonating part 120 is formed on the substrate 110. In this example, the resonating part 120 is obtained by forming a sacrificial layer (not illustrated) on the substrate 110 and sequentially laminating the membrane layer 150, the first electrode 121, the piezoelectric layer 123, the second electrode 125, and the protection layer 127 on the sacrificial layer and the substrate 110. Further, after the membrane layer 150 is formed on the sacrificial layer, the air gap 130 is formed by afterward removing the sacrificial layer.

The first electrode 121 and the second electrode 125 are formed in a necessary pattern by forming a conductive layer, depositing a photoresist on the conductive layer, performing a patterning using a photolithography process, and then removing unnecessary portions using the patterned photoresist as a mask.

According to the illustrated embodiment, the first electrode 121 may be formed of a molybdenum (Mo) material, and the second electrode 125 may be formed of ruthenium (Ru). However, the materials of the first and second electrodes 121 and 125 are not limited thereto, and the first electrode 121 and the second electrode 125 may be formed of various metals such as gold, ruthenium, aluminum, platinum, titanium, tungsten, palladium, chrome, nickel, and the like, as needed.

Further, the piezoelectric layer may be formed of aluminum nitride AlN. However, the material of the piezoelectric layer 123 is not limited thereto, and the piezoelectric layer 123 may be formed of various piezoelectric materials such as zinc oxide (ZnO), quartz, and the like.

The protection layer 170 may be formed of an insulating material. The insulating material may include a silicon oxide based material, a silicon nitride based material, and an aluminum nitride based material.

Next, the connection electrodes 180 and 190 for a frequency trimming are formed on the first electrode 121 and the second electrode 125. The connection electrodes 180 and 190 may be formed on the first and second electrodes 121 and 125, and may penetrate through the protection layer 127 or the piezoelectric layer 123 to be bonded to the electrodes.

The first connection electrode 180 may be formed by partially removing the protection layer 127 and the piezoelectric layer 123 by the etching to externally expose the first electrode 121, and then depositing gold (Au), copper (Cu), or the like on the first electrode 121.

Similarly, the second connection electrode 190 may be formed by partially removing the protection layer 127 by the etching to externally expose the second electrode 125, and then depositing gold (Au), copper (Cu), or the like on the second electrode 125.

Thereafter, after confirming characteristics of the resonating part 120 or the filter and performing a necessary frequency trimming using the connection electrodes 180 and 190, the air gap 130 may be formed.

As noted above, the air gap 130 is formed by removing the sacrificial layer. As a result, the resonating part 120 according to FIG. 3 is completed.

Next, referring to FIG. 4, the cap 140 is formed to protect the resonating part 120 from an external environment. The cap 140 may be formed by wafer bonding at a wafer level. That is, a substrate wafer on which a plurality of unit substrates 110 are disposed, and a cap wafer on which a plurality of caps 140 are disposed may be bonded to each other to be integrally formed.

In this case, the substrate wafer and the cap wafer which are bonded to each other may be diced by a dicing process later to be divided into a plurality of individual acoustic resonators.

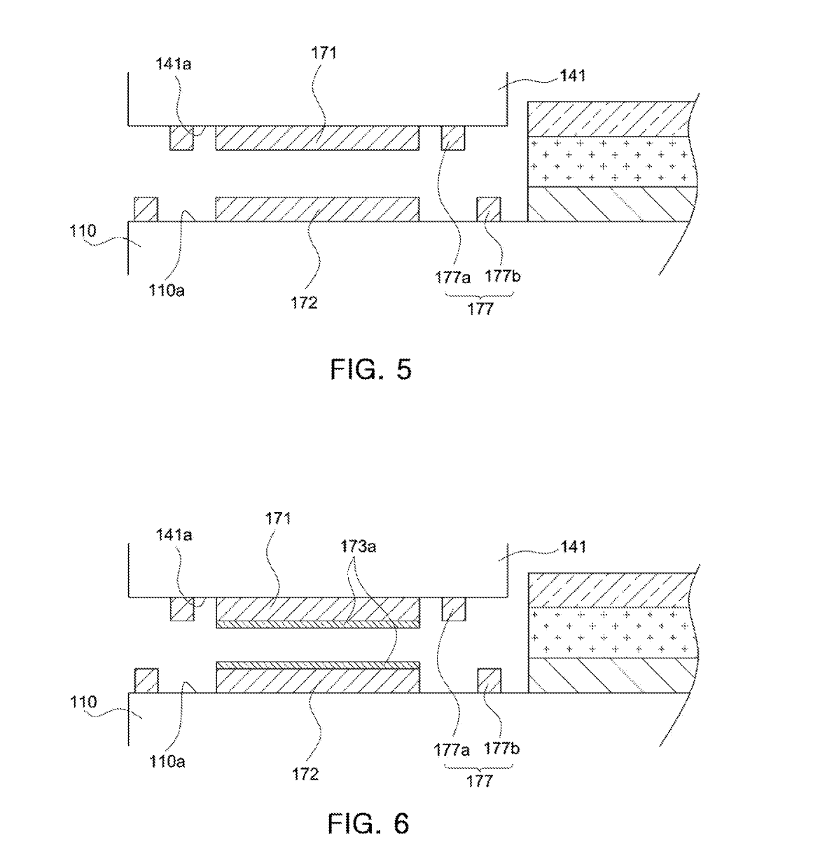

In the operation of bonding the cap 140 to the substrate, as illustrated in FIG. 5, an operation in which the first metal layer 171 is first formed on the bonding surface 141a of the cap 140 and the second metal layer 172 is formed on the bonding surface 110a of the substrate 110 are performed. In this example, the blocking block 177 is formed together with the first and second metal layers 171 and 172. That is, the blocking block 177 and the first and second metal layers 171 and 172 are formed substantially concurrently in the same process.

The first and second metal layers 171 and 172 and the blocking block 177 are formed on the cap 140 or the substrate 110 by a deposition method, or the like, but are not limited thereto. Further, the first and second metal layers 171 and 172 and the blocking block 177 may be formed of the same copper (Cu) material. Thus, because the blocking block 177 may be formed together with the first and second metal layers 171 and 172 in the process of forming the first and second metal layers 171 and 172, a separate process of manufacturing the blocking block 177 may not be required.

Next, referring to FIG. 6, bonding layers 173a is formed on a surface of the first metal layer 171 and a surface of the second metal layer 172, respectively. In this example, the bonding layers 173a are finally formed to be the third metal layer 173. The bonding layers 173a may be formed of Sn, and may be formed on the surface of the first metal layer 171 and the surface of the second metal layer 172 by the depositing method, or the like.

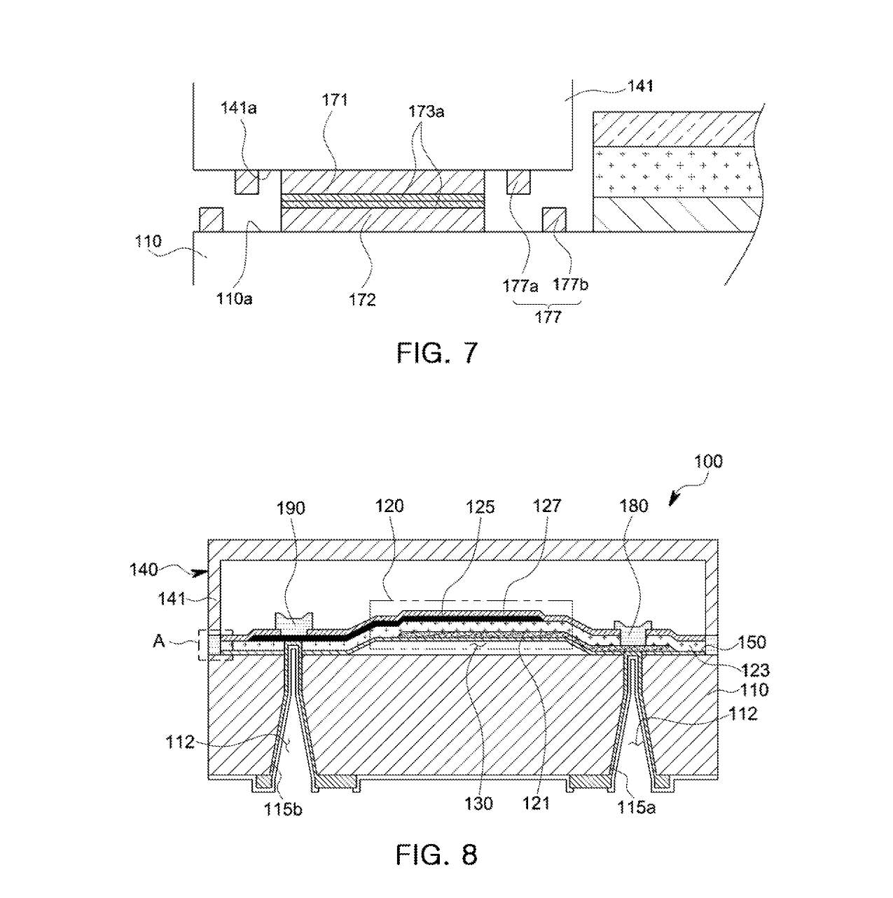

Next, referring to FIG. 7, the cap 140 is seated on the substrate 110. In addition, the bonding layer 173a formed on the cap 140 and the bonding layer 173a formed on the substrate 110 are bonded to each other by performing heating and pressing. In this process, the bonding layers 173a may be melted and then cured to be bonded to each other, and may be formed to be the third metal layer 173. As a result, the bonded part 175 illustrated in FIG. 2 may be obtained.

In this example, portions of the molten bonding layers 173a that flow outside of the first metal layer 171 and the second metal layer 172 are prevented from further leakage by the blocking block 177. As a result, the molten bonding layers 173a may be positioned only in an inner space of the blocking block 177 and may not flow to the outside of the blocking block 177.

Next, referring to FIG. 8, after the via holes 112 are formed in the substrate 110, the connection conductors 115a and 115b are formed in the via holes 112.

The connection conductors 115a and 115b may be manufactured by forming a conductive layer on the inner surfaces of the via holes 112. For example, the connection conductors 115a and 115b may be formed by depositing, coating, or providing a conductive metal (e.g., gold, copper, or the like) along the inner walls (112a and 112b) of the via holes 112.

Next, the acoustic resonator 100 illustrated in FIG. 1 is completed by forming the external electrodes 117 on the lower surface of the substrate 110.

The external electrode 117 is formed on the connection conductors 115a and 115b extended to the lower surface of the substrate 110. As the external electrodes 117, solder balls formed of a Sn material may be used, but the external electrodes 117 are not limited thereto.

In the method of manufacturing the acoustic resonator according to the example having the configuration as described above, because the blocking block may be formed together in the operation of forming the first and second metal layers, a separate process of forming the blocking block may not be required.

Further, the example in which the bonding layers melted in the process of forming the bonded part excessively flow to the outside of the first and second metal layers may be prevented by the blocking block.

Meanwhile, the acoustic resonator and the method of manufacturing the same are not limited to the above-mentioned embodiments, and may be variously modified.

For example, the above mentioned embodiment illustrates an example in which the cap is attached to the substrate and the connection conductors are then formed. However, the present disclosure is not limited thereto, and may be variously modified. For example, after the connection conductors are first formed, the cap may be attached to the substrate, and so forth.

In addition, the above-mentioned embodiment illustrates an example in which a cross section of the blocking block is formed in a quadrangular shape. However, the present disclosure is not limited thereto, and may be variously modified. For example, the cross section of the blocking block may be formed in a triangular shape or a trapezoidal shape, and so forth.

As set forth above, according to the examples described above, the acoustic resonator may include the blocking block blocking the flow of the bonding layer melted by the heat when the cap and the substrate are bonded. As a result, the blocking block may prevent the flow of the molten bonding layer to the outside of the bonded portion.

Further, in the example of a method of manufacturing the acoustic resonator described above, because the blocking block may be formed together in the operation of forming the first and second metal layers, the separate process of forming the blocking block may not be required. As a result, the acoustic resonator may be easily manufactured.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic resonator comprising:
a resonating part disposed on a substrate;
a cap accommodating the resonating part and bonded to the substrate; and
a bonded part bonding the cap and the substrate to each other,
wherein the bonding part comprises at least one block disposed between a bonding surface of the cap and a bonding surface of the substrate to block a leakage of a bonding material that forms the bonded part during a bonding operation.

2. The acoustic resonator of claim 1, wherein the bonded part comprises:
a first metal layer disposed on the bonding surface of the cap;
a second metal layer disposed on the bonding surface of the substrate; and
a third metal layer interposed between the first metal layer and the second metal layer.

3. The acoustic resonator of claim 2, wherein the third metal layer comprises tin (Sn).

4. The acoustic resonator of claim 2, wherein the first and second metal layers comprise copper (Cu) or gold (Au).

5. The acoustic resonator of claim 2, wherein the block is spaced apart from the first and second metal layers by a predetermined distance.

6. The acoustic resonator of claim 1, wherein the block is disposed on at least one of the bonding surface of the cap and the bonding surface of the substrate.

7. The acoustic resonator of claim 1, wherein the at least one block comprises a first block disposed on the bonding surface of the cap and a second block disposed on the bonding surface of the substrate.

8. The acoustic resonator of claim 7, wherein the first block and the second block are disposed at positions that do not face each other.

9. The acoustic resonator of claim 7, wherein the first block and the second block are disposed not to contact each other.

10. A method of manufacturing an acoustic resonator, the method comprising:
forming a resonating part on a substrate; and
bonding a cap to the substrate,
wherein the bonding of the cap comprises providing a block on at least one of a bonding surface of the cap and a bonding surface of the substrate.

11. The method of claim 10, wherein the bonding of the cap comprises:
forming a first metal layer on the bonding surface of the cap and forming a second metal layer on the bonding surface of the substrate; and
forming a third metal layer between the first metal layer and the second metal layer to bond the cap and the substrate to each other.

12. The method of claim 11, wherein the block comprises the same material as that of the first metal layer or the second metal layer, and is formed during a same process with the first metal layer or the second metal layer.

13. The method of claim 11, wherein the block is formed at a position spaced apart from the first metal layer or the second metal layer by a predetermined distance.

14. The method of claim 11, wherein the forming of the third metal layer comprises melting and curing the third metal layer; and
the block blocks a leakage of the molten third metal layer.

15. The method of claim 10, wherein the block is formed along an edge of the bonding surface of the cap or the bonding surface of the substrate.

16. The method of claim 11, wherein a material forming the third metal layer has a lower melting point than a material forming the block.

17. An acoustic resonator comprising:
a cap disposed over a resonating part and bonded to a substrate;
a bonded part disposed between a bonding surface of the cap and the substrate,
wherein the bonded part comprises a block disposed along an edge of the bonding surface of the cap and a bonding material disposed on the bonding surface and abutting a sidewall of the block.

18. The acoustic resonator of claim 17, wherein the bonded part comprises a first metal layer disposed on the bonding surface of the cap, the first metal layer being spaced apart from the block; and
the bonding material extends from a first area between from the first metal layer and the substrate to a second area between the first metal layer and the sidewall of the block.

19. The acoustic resonator of claim 17, wherein the block and the first metal layer are formed of a same material; and
the bonding material comprises a material having a lower melting point than the material forming the block and the first metal layer.
